(19) United States
(12) Patent Application Publication
(10) Pub. No.: US 2025/0275262 A1
(43) Pub. Date: Aug. 28, 2025

(54) AVALANCHE PHOTODIODES HAVING SEPARATE ABSORPTION CHARGE AND MULTIPLICATION (SACM) HETEROSTRUCTURES

(71) Applicant: Ohio State Innovation Foundation, Columbus, OH (US)

(72) Inventors: Sanjay KRISHNA, Plain City, OH (US); Seunghyun LEE, Columbus, OH (US); Hyemin JUNG, Columbus, OH (US)

(21) Appl. No.: 18/858,096

(22) PCT Filed: Apr. 18, 2023
(86) PCT No.: PCT/US2023/018957

§ 371 Date: Oct. 18, 2024

Related U.S. Application Data
(60) Provisional application No. 63/394,544, filed on Aug. 2, 2022.
(60) Provisional application No. 63/332,002, filed on Apr. 18, 2022.

(51) Int. Cl. H10F 30/225

(52) U.S. Cl. CPC H10F 30/2255

(57) ABSTRACT

Avalanche photodiode (APDs) including a separate absorption charge and multiplication (SACM) heterostructure are described herein. A device may include a substrate and a separate absorption charge and multiplication (SACM) heterostructure disposed on the substrate. The SACM heterostructure may include an absorber comprising gallium arsenide antimonide (GaAsSb) and a multiplier comprising aluminum gallium arsenide antimonide (AlGaAsSb). The device exhibits a gain (M) of greater than 50.

### CROSS-REFERENCE TO RELATED APPLICATIONS

This application claims the benefit of U.S. provisional patent application No. 63/332,002, filed on Apr. 18, 2022, and titled “AVALANCHE PHOTODIODES HAVING SEPARATE ABSORPTION CHARGE AND MULTIPLICATION (SACM) HETEROSTRUCTURES,” and U.S. provisional patent application No. 63/394,544, filed on Aug. 2, 2022, and titled “AVALANCHE PHOTODIODES HAVING SEPARATE ABSORPTION CHARGE AND MULTIPLICATION (SACM) HETEROSTRUCTURES,” the disclosures of which are expressly incorporated herein by reference in their entirety.

### STATEMENT REGARDING FEDERALLY FUNDED RESEARCH

This invention was made with government support under grant/contract number N00014-17-1-2440 awarded by the Office of Naval Research. The government has certain rights in the invention.

### BACKGROUND

Light detection and ranging (LiDAR) systems use light to measure distances. LiDAR can be used for navigation, automation, and robotics, among other applications. LiDAR systems illuminate an area and measure the reflected light from surfaces in the area. The accuracy of the measurement of the reflected light is important to the accuracy of the LiDAR system. In some LiDAR systems, photodiodes can be used to convert the reflected light into an electrical signal that can be measured. Photodiodes can be characterized by their excess noise factor, gain, and quantum efficiency, among other parameters. Improvements in photodiodes, including improved excess noise factors, gains, and/or quantum efficiencies can improve the performance of LiDAR systems and any other devices or systems that include photodiodes.

### SUMMARY

Disclosed herein are avalanche photodiode (APDs) including a separate absorption charge and multiplication (SACM) heterostructure. Also disclosed herein are methods for fabricating an avalanche photodiode (APD) including a separate absorption charge and multiplication (SACM) heterostructure.

In some aspects, the techniques described herein relate to an avalanche photodiode (APD) including: a substrate; and a separate absorption charge and multiplication (SACM) heterostructure disposed on the substrate, wherein the SACM heterostructure includes: an absorber including gallium arsenide antimonide (GaAsSb); and a multiplier including aluminum gallium arsenide antimonide (AlGaAsSb), wherein the APD exhibits a gain (M) of greater than 50.

In some aspects, the techniques described herein relate to a APD, wherein the APD exhibits M of greater than 50 at about 1550 nm.

In some aspects, the techniques described herein relate to a APD, wherein the APD exhibits M of greater than 100 at about 1550 nm.

In some aspects, the techniques described herein relate to a APD, wherein APD exhibits an excess noise factor of less than 3 at M of about 70.

In some aspects, the techniques described herein relate to a APD, wherein APD exhibits an excess noise factor of 2.2 or less at M of about 50.

In some aspects, the techniques described herein relate to a APD, wherein the SACM heterostructure further includes a charge layer arranged between the absorber and the multiplier.

In some aspects, the techniques described herein relate to a APD, wherein the charge layer includes doped AlGaAsSb.

In some aspects, the techniques described herein relate to a APD, wherein the charge layer has a total doping concentration is about 2.1×10¹² cm⁻².

In some aspects, the techniques described herein relate to a APD, wherein the charge layer has a p-type doping of between 1×10¹⁶ cm⁻³ and 1×10¹ cm⁻³.

In some aspects, the techniques described herein relate to a APD, wherein the charge layer is between 10 nm and 200 nm thick.

In some aspects, the techniques described herein relate to a APD, wherein the SACM heterostructure further includes a grading layer arranged between the absorber and the multiplier.

In some aspects, the techniques described herein relate to a APD, wherein the grading layer includes linearly-graded or step-graded AlGaAsSb.

In some aspects, the techniques described herein relate to a APD or claim 12, wherein the grading layer includes unintentionally doped (UID) AlGaAsSb.

In some aspects, the techniques described herein relate to a APD, wherein the grading layer is approximately 90 nm thick.

In some aspects, the techniques described herein relate to a APD, wherein the grading layer is between 50 nm and 2000 nm thick.

In some aspects, the techniques described herein relate to a APD, wherein a composition of Al in the grading layer is graded from 0% to 85%.

In some aspects, the techniques described herein relate to a APD, wherein the substrate includes indium phosphide (InP).

In some aspects, the techniques described herein relate to a APD, wherein the multiplier is arranged in a high electric field region.

In some aspects, the techniques described herein relate to a APD, wherein the multiplier is between 300 nm and 3000 nm thick.

In some aspects, the techniques described herein relate to a APD, wherein the multiplier is about 1020 nm thick.

In some aspects, the techniques described herein relate to a APD, wherein the absorber is arranged in a low electric field region.

In some aspects, the techniques described herein relate to a APD, wherein the absorber is between 300 nm and 1000 nm thick.

In some aspects, the techniques described herein relate to an avalanche photodiode (APD) including: a substrate; and a separate absorption charge and multiplication (SACM) heterostructure disposed on the substrate, wherein the SACM heterostructure includes: an absorber including gallium arsenide antimonide (GaAsSb); and a multiplier including aluminum gallium arsenide antimonide (AlGaAsSb), wherein APD exhibits an excess noise factor of less than 3.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1A illustrates an example embodiment of GaAsSb/AlGaAsSb separate absorption charge and multiplication (SACM) heterostructure for avalanche photodiodes (APDs) according to an implementation described herein.

FIG. 1B illustrates an example embodiment of GaAsSb/AlGaAsSb SACM heterostructure for avalanche photodiodes (APDs) according to an implementation described herein.

FIG. 2A illustrates a perspective view of an example heterostructure schematic of an implementation of a GaAsSb/AlGaAsSb SACM APD grown by solid source molecular beam epitaxy.

FIG. 2B illustrates a microscope-enlarged view of example fabricated devices according to the example implementation of the present disclosure with labeled diameters of the devices in μm.

FIG. 2C illustrates a modeled electric field profile showing the GaAsSb in the low field region below the tunneling threshold and the AlGaAsSb multiplier in the high field region to obtain large avalanche gain for an example implementation of the present disclosure.

FIG. 2D illustrates an example band profile for the device at zero bias, punch-through (42 V), and near breakdown voltage (67 V) according to an example implementation of the present disclosure.

FIG. 3A illustrates a plot of capacitance-voltage results according to an example implementation of the present disclosure.

FIG. 3B illustrates a plot of external spectral quantum efficiency (without anti-reflection coatings) according to an example implementation of the present disclosure.

FIG. 3C illustrates absorption coefficients of two example GaAsSb p-i-n (PIN) diodes (PIN1 and PIN2) according to an example implementation of the present disclosure.

FIG. 3D illustrates M−1 versus reverse bias according to an example implementation of the present disclosure.

FIG. 3E illustrates F as a function of M for AlGaAsSb PIN structures with three different multiplier thicknesses according to an example implementation of the present disclosure.

FIG. 4A illustrates measured CV result of the SACM APD and a doping profile 402 according to an example implementation of the present disclosure.

FIG. 4B illustrates bias-dependent dark current for different diode sizes and photocurrent (Iph) for 200 μm diameter device at room temperature according to an example implementation of the present disclosure.

FIG. 4C illustrates M obtained with a 1550 nm illumination showing a maximum gain of 278 according to an example implementation of the present disclosure.

FIG. 4D illustrates measured QE spectra of the SACM APD at various reverse bias voltages according to an example implementation of the present disclosure.

FIG. 4E illustrates noise factor, F, as a function of the multiplication gain, M according to an example implementation of the present disclosure.

FIG. 5A illustrates frequency of GaAsSb/AlGaAsSb APDs as a function of the operating bias according to an example implementation of the present disclosure.

FIG. 5B illustrates the 3 dB bandwidth and Gain Bandwidth Product (GBP) reach 0.7 GHz and 11 GHz at 65 V, respectively according to an example implementation of the present disclosure.

FIG. 5C illustrates measured gain, M, as a function of reverse bias at three different temperatures, 296, 333, and 353 K according to an example implementation of the present disclosure.

FIG. 5D illustrates Cbd versus total depletion width for APDs of various materials, according to an example implementation of the present disclosure.

FIG. 6A illustrates excess noise values for an example implementation of the present disclosure.

FIG. 6B illustrates a/f ratio at M=1.1 versus spin orbit energy for various material systems, according to an example implementation of the present disclosure.

FIG. 7 compares an example implementation of the present disclosure with a non-optimized GaAsSb/AlGaAsSb SACM APD to other APDs.

FIG. 8A illustrates a table of additional example materials, doping concentrations, and thicknesses, according to example implementations of the present disclosure.

FIG. 8B illustrates a table of additional example materials, doping concentrations, and thicknesses, according to example implementations of the present disclosure.

FIG. 8C illustrates a table of additional example materials, doping concentrations, and thicknesses, including epitaxial structures of PIN GaAsSb Photodiodes, according to example implementations of the present disclosure.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

As used herein, the terms “about” or “approximately” when referring to a measurable value such as an amount, a percentage, and the like, is meant to encompass variations of ±20%, ±10%, ±5%, or ±1% from the measurable value.

Described herein are avalanche photodiodes (APD), for example a GaAsSb—AlGaAsSb heterostructure avalanche photodiode. The devices (e.g., APD) described herein can use InGaAs, GaAsSb and InGaAs/GaAsSb absorber and AlGaAsSb multiplier in a separate absorption charge and multiplication (SACM) configuration. In a SACM heterostructure, the absorber is placed in a low electric field region (below the tunneling threshold) and the multiplier is placed in a large field to increase the multiplication. Promising results have been demonstrated using an embodiment of the device with a GaAsSb absorber and AlGaAsSb multiplier on an InP substrate.

There is a need for high gain and large quantum efficiency avalanche photodiodes (APDs) for increased sensitivity. Among other applications, implementations of the present disclosure are needed for longer wavelength light detection and ranging (LiDAR) applications where the sensitivity is limited by the noise caused by the detector. Another example application that will benefit from high performance APDs is the high-speed optical communication market using passive optical networks (PON).

A figure of merit for an APD is the gain-quantum efficiency and gain-bandwidth product. The thickness of the device described herein and the area of the device described herein are optimized to obtain a high speed or high sensitivity. Variations of the design of the device described herein including composition, thickness and doping can be altered to achieve this goal.

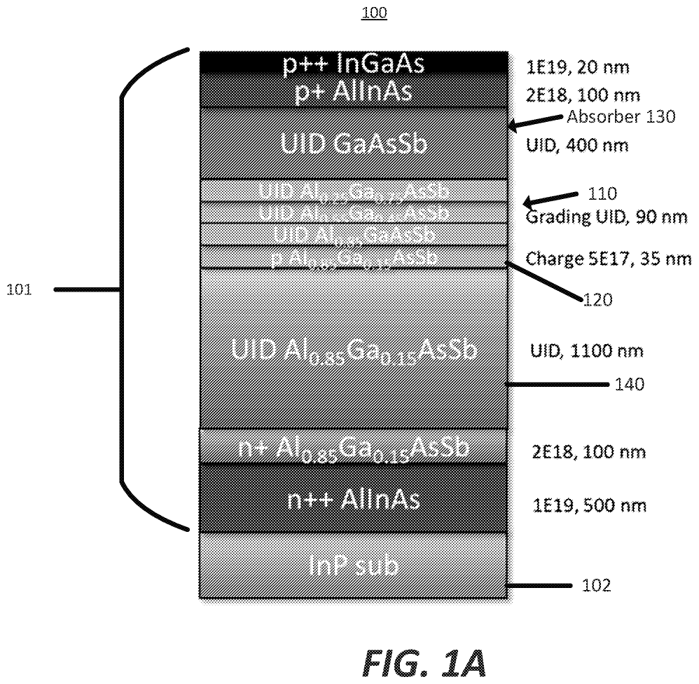

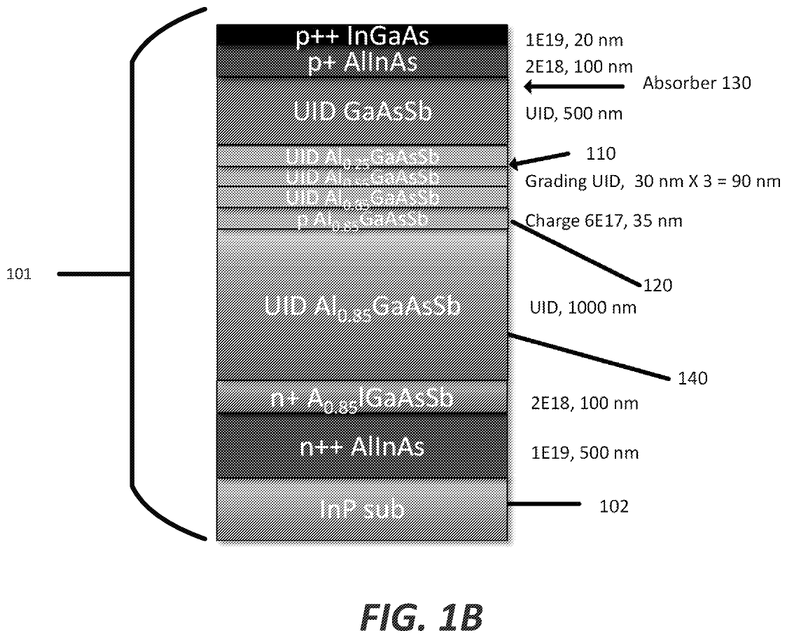

With reference to FIG. 1A, an example APD 100 according to an implementation of the present disclosure is shown.

The example APD includes an SACM heterostructure 101 disposed on a substrate 102. As shown in FIG. 1A, the substrate 102 can be an InP substrate in some implementations of the present disclosure, but it should be understood that InP is a non-limiting example.

The SACM heterostructure 101 can include an absorber 130 comprising gallium arsenide antimonide (GaAsSb). Optionally, the absorber 130 can be arranged in a low electric field region. The present disclosure contemplates that different thicknesses of absorber 130 can be used. In the example implementation shown in FIG. 1A, the absorber can be about 400 nm thick. In other example implementations, the absorber 130 can be about 460 nm thick or about 500 nm thick, or optionally, any thickness between 300 nm and 1000 nm.

The SACM heterostructure 101 can further include a multiplier 140. In some implementations, the multiplier 140 can include aluminum gallium arsenide antimonide (AlGaAsSb), Optionally, the multiplier 140 can be arranged in a high electric field region. The present disclosure contemplates that different thicknesses of multiplier 140 are possible. For example, in some implementations the multiplier 140 is about 1100 nm thick, and in other implementations the multiplier 140 can be about 1020 nm thick, or optionally, any thickness between 300 nm and 3000 nm.

In some implementations, the APD 100 can exhibit a gain (M) of greater than 50. For example, the APD 100 can exhibit M of greater than 50 at about 1550 nm. Optionally, in some implementations, the APD 100 can exhibit M of greater than 70 at about 1550 nm, and in some implementations, the APD 100 can exhibit M of greater than 100 at about 1550 nm. Again, it should be understood that these gains are only non-limiting examples.

Alternatively or additionally, implementations of the APD 1.00 can exhibit low excess noise factors. Optionally, in some implementations, the APD 100 can exhibit an excess noise factor of less than 3. As a non-limiting example, in some implementations of the present disclosure, the APD 100 can exhibit an excess noise factor of less than 3 at M of about 70. Alternatively or additionally, the APD 100 can exhibit an excess noise factor of 2.2 or less at M of about 50. It should be understood that, in some implementations of the present disclosure, the APD 100 can exhibit any combination of the example low excess noise factors given herein at any of the example gains given herein. For example, implementations of the present disclosure can exhibit both a gain of greater than 50 at wavelength of 1550 nm and an excess noise factor of less than 3, or a gain of greater than 100 at wavelength of 1550 nm and an excess noise factor of less than 2.2.

In some implementations, the SACM heterostructure 101 can include a charge layer 120 arranged between the absorber 130 and the multiplier 140. As a non-limiting example, the charge layer 120 can include doped AlGaAsSb. It should be understood that different doping concentrations of the charge layer 120 are possible. As non-limiting examples, the charge layer 120 can optionally have a total doping concentration of about 2.1×10¹² cm⁻², and alternatively or additionally can have a p-type doping of about 6×10¹⁷ cm⁻². It should be understood that in some implementations of the present disclosure, the p-type doping of the charge layer 120 can be any amount from 1×10¹⁶ cm⁻³ to 1×10¹⁸ cm⁻³.

It should also be understood that different thicknesses of charge layer 120 are possible in different implementations of the present disclosure. For example, in some implementations, the charge layer 120 is about 35 nm thick. It should be understood that in some implementations of the present disclosure, the charge layer 120 can be between 10 nm and 200 nm thick.

In some implementations, the APD 100 can include a grading layer 110. Optionally the grading layer 110 can be arranged between the absorber 130 and the multiplier 140 in the SACM heterostructure. Optionally, the grading layer 110 can include linearly-graded and/or step-graded AlGaAsSb. Alternatively or additionally, the grading layer can include unintentionally doped (UID) AlGaAsSb. In some implementations, the composition of Al in the grading layer 110 can be graded from 0% to 85% as shown in FIG. 1A.

The present disclosure contemplates that different thicknesses of grading layer are possible. As a non-limiting example, in some implementations, the grading layer 110 can be approximately 90 nm thick. It should be understood that in some implementations of the present disclosure, the grading layer 110 can be between 50 nm and 2000 nm thick.

It should be understood that the materials and dimensions shown in FIG. 1A are only intended as non-limiting examples, and each part of the SACM heterostructure can include different compositions or thicknesses in alternative implementations of the present disclosure.

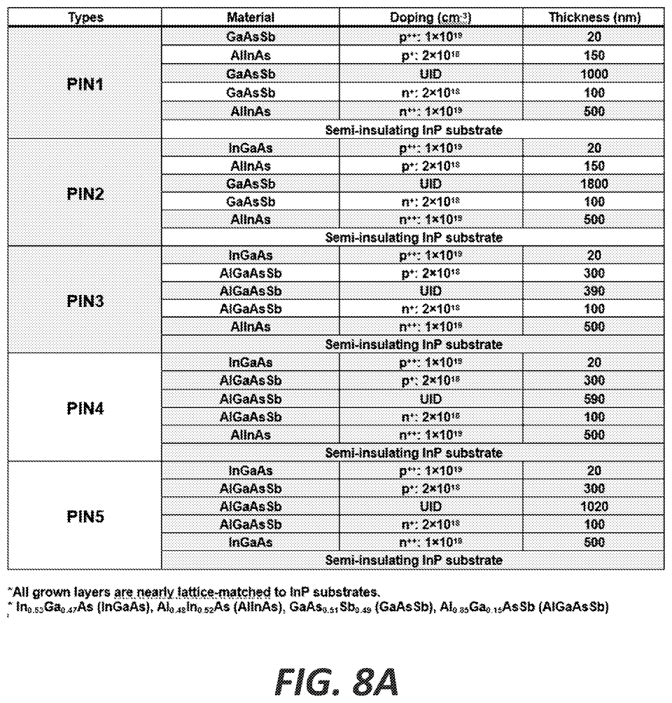

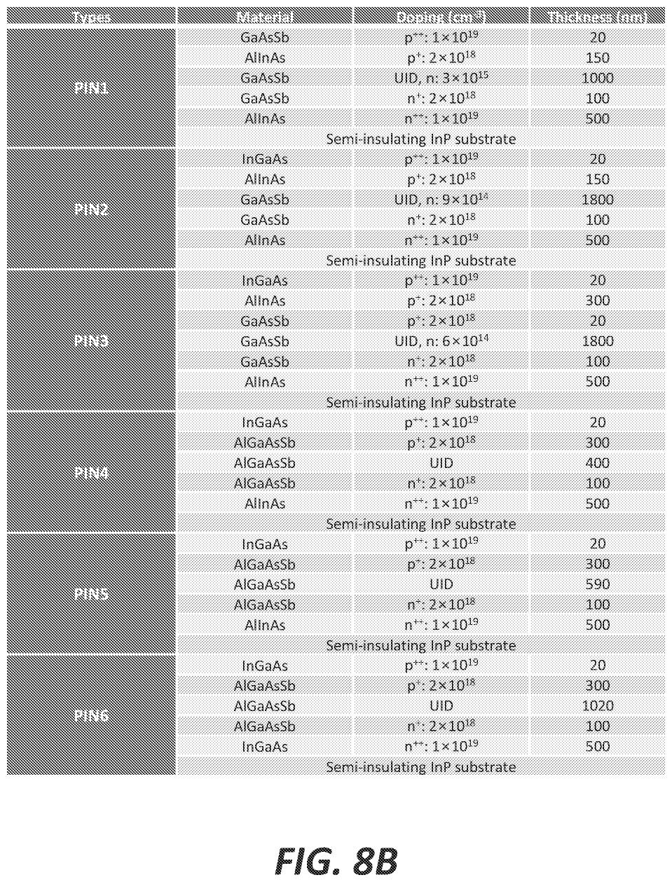

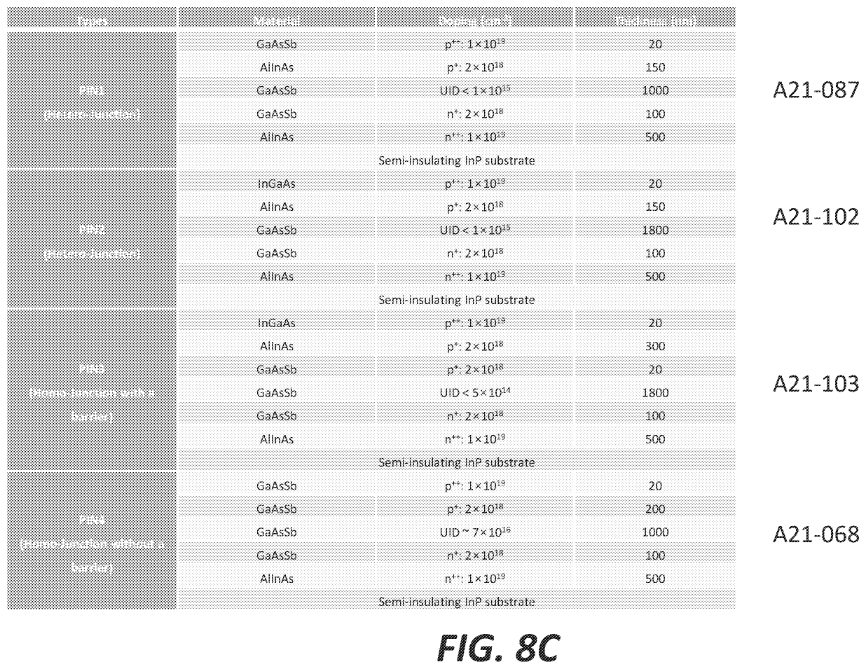

FIG. 1B illustrates another example implementation of an APD 150 including the components shown in FIG. 1A, but with different example thicknesses and doping concentrations. For example, in FIG. 1B, the multiplier 140 is 1000 nm thick, while in FIG. 1A, the multiplier is 1100 nm thick. Likewise, in FIG. 1B, the absorber 130 is 500 nm thick, but in FIG. 1A, the absorber is 400 nm thick. And, as yet another non-limiting example, the charge layer has a doping concentration of 5×10¹⁷ cm⁻² in FIG. 1A, while in FIG. 1B it has a doping concentration of 6×10¹⁷ cm². Again, the specific doping concentrations, thicknesses, and layers shown in FIGS. 1A and 1B are intended only as non-limiting examples, and the present disclosure contemplates different combinations of doping concentrations, layers, and thicknesses. Additional non-limiting examples are described throughout the present disclosure, and illustrated, for example in FIGS. 8A-8C.

### Examples

The following examples are put forth so as to provide those of ordinary skill in the art with a complete disclosure and description of how the compounds, compositions, articles, devices and/or methods claimed herein are made and evaluated, and are intended to be purely exemplary and are not intended to limit the disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

A study was performed of example implementations of the present disclosure. As non-limiting examples, the studied implementations can be used for LiDAR systems can be used in applications ranging from space-borne instruments for greenhouse gas emission [1,2] to accurate 3D-sensing [2] and mapping [2] in urban environments for next-generation fully-autonomous vehicles. For these “photon-starved” applications, avalanche photodiodes (APD) can provide high detection sensitivity due to their internal gain (M). However, this gain can come at the cost of excess noise due to the stochastic nature of the impact ionization process. McIntyre's local field theory [3] defines the excess noise factor (F) as

$$F = kM + ( 1 - k ) ( 2 - 1 / M )$$

where k=β/α (the ratio of impact ionization coefficient of the hole, β, and electron, α). This F sets a limit to the maximum useful gain of a given device, meaning that high sensitivity APDs requiring a large signal-to-noise ratio necessitate the use of avalanche materials with a small k.

Many LIDAR systems operate at 905 nm using silicon APD receivers due to their high sensitivity, reliability, and low cost. However, the wavelength of these LiDAR systems can be limited by the bandgap of silicon to less than 1100 nm. But the wavelength of 1550 nm can be relevant for long distance applications because higher laser powers can be used (being eye-safe), and because it is less affected by the solar background and atmospheric turbulence.

The studied example implementations of the present disclosure includes improvements to linear mode APDs at 1550 nm, which can be used, for example, to improve LiDAR systems. Conventional APDs include In0.53Ga0.47As (InGaAs) absorber and InP or InAlAs multiplier in a separate absorption, charge, and multiplication (SACM) architecture with an M of 30 and a large F>0.10 [4,5]. This relatively small gain and large excess noise limits the performance of these APDs.

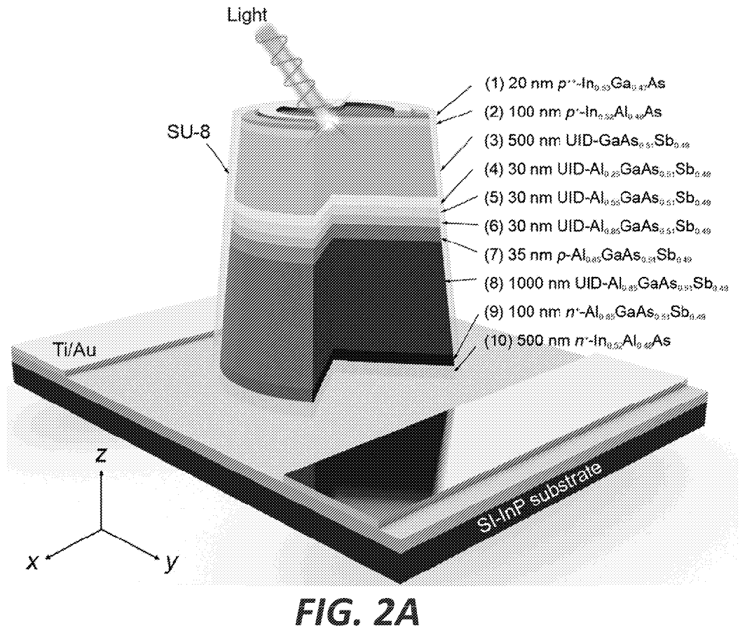

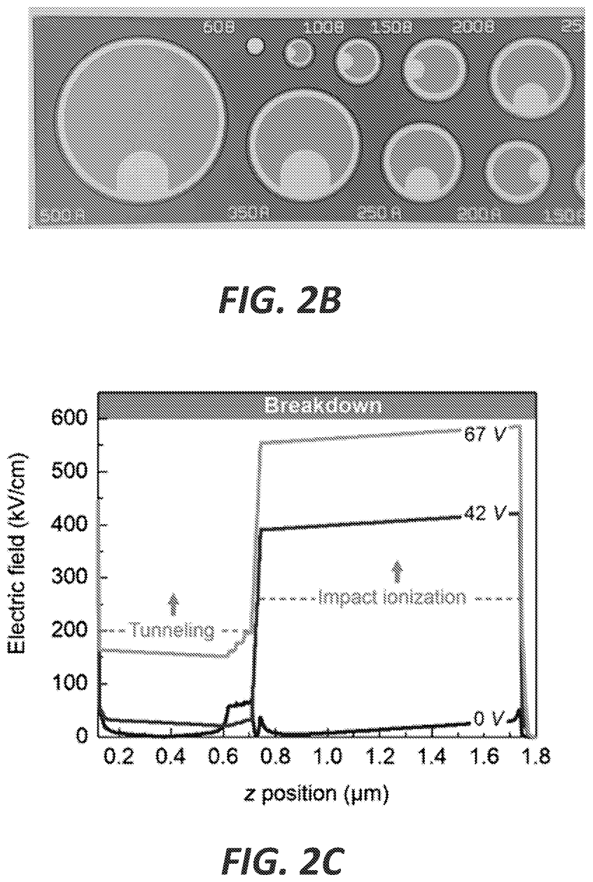

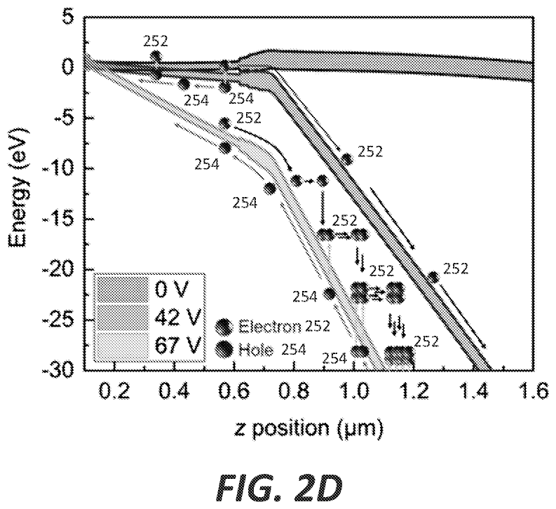

FIG. 2A illustrates a perspective view of a heterostructure schematic 200 of the GaAsSb/AlGaAsSb SACM APD grown by solid source molecular beam epitaxy.

FIG. 2B illustrates a microscope-enlarged view of example fabricated devices according to the example embodiment with labeled diameters of the devices in μm.

FIG. 2C illustrates a modeled electric field profile of the structure showing the GaAsSb in the low field region below the tunneling threshold and the AlGaAsSb multiplier in the high field region to obtain large avalanche gain for an example implementation. FIG. 2D illustrates an example band profile for the device at zero bias, punch-through (42 V), and near breakdown voltage (67 V). FIG. 2D includes a conceptual illustrations of electrons 252 and holes 254 to show how photogenerated carriers travel from the absorber to the multiplier depending on the applied bias voltages.

The example implementation exhibits significant advancement in the gain and excess noise of a room temperature (RT, T=296 K), 1550 nm APD using a GaAs0.5Sb0.5/Al0.85Ga0.15As0.56Sb0.44 (GaAsSb/AlGaAsSb) SACM architecture. In this implementation, the AlGaAsSb multiplier experiences a high electric field (<600 kV/cm) to achieve a large avalanche gain, while the GaAsSb absorber has a low electric field (<200 kV/cm) region to minimize the tunneling leakage current. The grading from the absorber to the multiplier is accomplished by inserting thin AlGaAsSb layers with two different AI compositions between 0 to 85%.

FIG. 2A shows a perspective view of the heterostructure design. FIG. 2B illustrates a microscope view of the example devices, FIG. 2C illustrates an example modelled electric field profile and FIG. 2D illustrates the band profile of the device. The structure incorporates advances on the AlGaAsSb multiplier [6,7] and the GaAsSb absorber. The structure was grown on semi-insulating InP substrates using solid source molecular beam epitaxy.

Testing of the absorber and multiplier for GAASSB/ALGAASSB SACM APDS was performed in the study.

Implementations of the present disclosure can include high-performance GaAs0.5Sb0.5 absorbers. An example SACM structure includes the use of a GaAsSb absorber as opposed to the conventionally used InGaAs. In the example structure, there were at least two benefits of using GaAsSb over InGaAs. The first was that the conduction and valence bands in the AlxGa1−xAsSb can be made to change continuously from the GaAsSb absorber to the AlGaAsSb multiplier without any large bandgap discontinuity. This can make it easier to extract the carriers by minimizing trapping and improving the speed of the devices. The second benefit is that it is easier to grade from GaAsSb to AlGaAsSb while maintaining lattice matched growth as it is mainly the group Ill compositions that need to change. By contrast, InGaAs has a Type 11 band alignment resulting in a larger conduction band offset (˜1 eV) between the last layer of grading (In0.52Al0.48As) and the AlGaAsSb multiplier [11,12]. Therefore, comparably simple and efficient grading may not be possible with an InGaAs absorber.

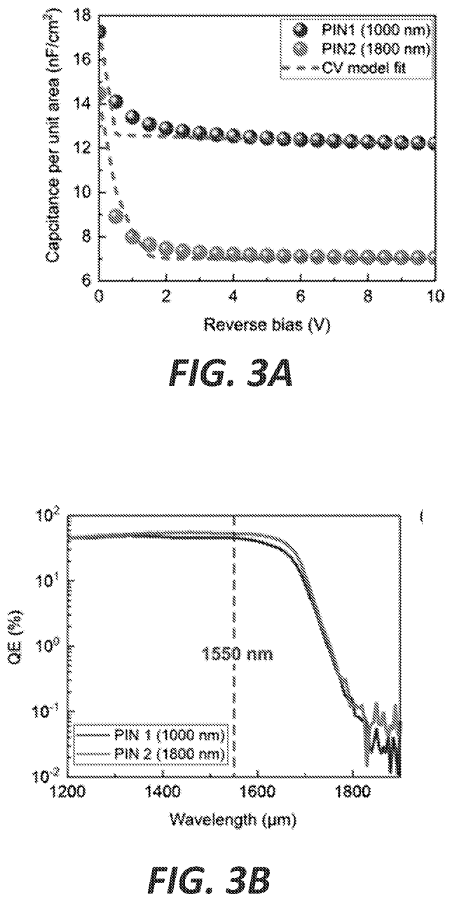

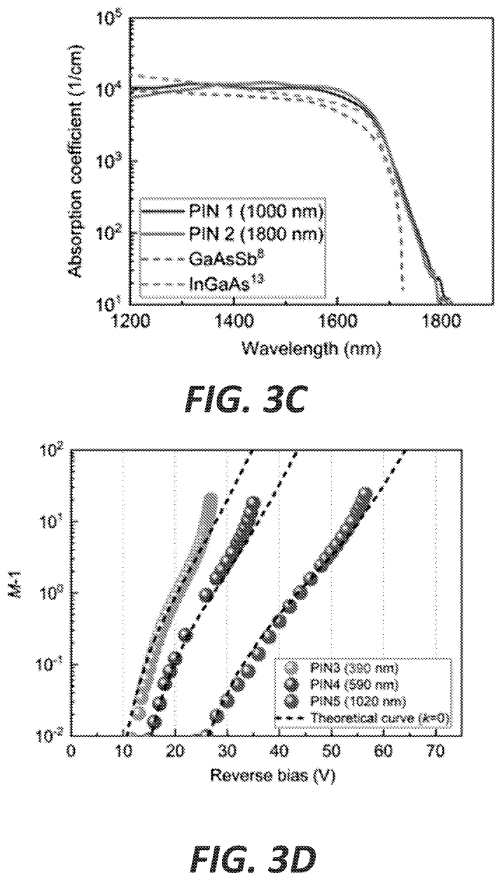

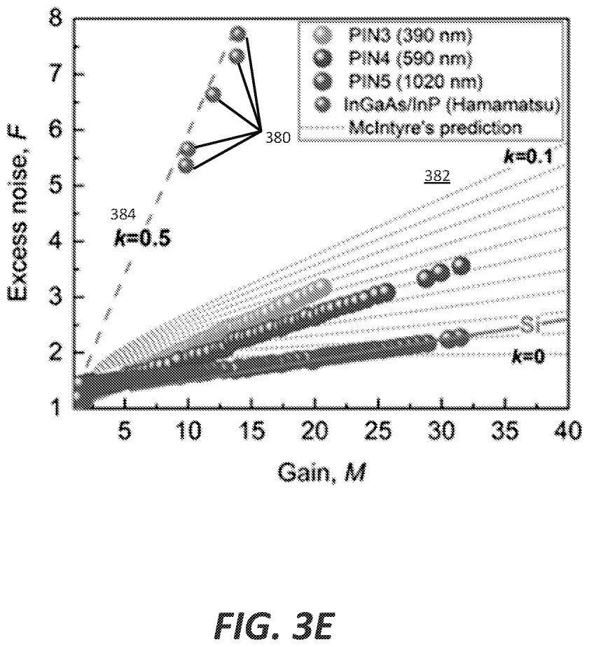

FIG. 3A illustrates a plot of capacitance-voltage results. FIG. 3B illustrates a plot of external spectral quantum efficiency (without anti-reflection coatings). FIG. 3C illustrates absorption coefficients of two example GaAsSb p-i-n (PIN) diodes (PIN1 and PIN2) compared with literature [8,13]. FIG. 3D illustrates M−1 versus reverse bias. FIG. 3E illustrates F as a function of M for AlGaAsSb p+-i-n+ structures with three different multiplier thicknesses. Dots 380 indicate F of InGaAs/InP Hamamatsu APD [4,5]. Dashed lines are the calculated McIntyre's noise curves with different k increasing from 0 to 0.1 in steps 382 of 0.01 and k=0.5 384.

To examine the performance of an example GaAsSb absorber, the study grew two example p+-i-n+ structures (PIN1 and PIN2). PIN1 and PIN2 were designed with two different unintentionally doped (UID) layer thicknesses, 1000 and 1800 nm, for measuring the background doping concentration and external quantum efficiency (QE). The details of the structures can be found in the Supplementary Material. Capacitance-voltage (CV) measurements were performed on PIN1 and PIN2 as shown in FIG. 3A. From this the background doping concentrations in the UID layers of PIN1 and PIN2 were found to be as low as 1×1015 cm-3. FIG. 3B shows the spectra of the measured QE for PIN1 and PIN2. The QE of PIN1 and PIN2 were 45% and 52.5%, respectively, at 1550 nm without anti-reflection (AR) coating, and the 50% cut-off wavelength was 1675 nm. The absorption coefficient of GaAsSb determined from the measured QE spectra is shown in FIG. 3C. The absorption spectra of PIN1 and PIN2 are very similar, indicating the high reproducibility of the growth. The absorption coefficients, while broadly similar to those previously reported, [7] are slightly higher in the range from 1400-1700 nm and are comparable to those of InGaAs [13]. In the SACM APD implementation, the next most important design parameter for the GaAsSb absorber is its tunneling threshold field. The study assumed the same tunneling threshold field (˜200 kV/cm) as for an InGaAs absorber in designing our SACM APD because of their similar bandgaps and electron-effective masses [14,15](FIG. 2C).

Implementations of the present disclosure can include extremely low excess noise Al0.85Ga0.15As0.56Sb0.44 multipliers. The gain and excess noise of three p+-i-n+ AlGaAsSb multipliers with varying UID layer thicknesses, 390 (PIN3), 590 (PIN4) and 1020 nm (PIN5), were investigated to support the SACM APD design. This study of the effects of thickness on avalanche characteristics can be used to select the best thickness for the multiplier in an SACM APD, maximizing M and minimizing the excess noise factor (F). Details of the growth and characterization of these structures are shown in FIGS. 8A-8C, where FIG. 8A illustrates a table with a first set of example materials, doping concentrations, and thicknesses. FIG. 8B and FIG. 8C illustrate additional example materials, doping concentrations, and thicknesses, that can be used as

The measurements on M and F described with reference to the study herein were taken using pure electron-initiated multiplication, which was achieved by using short-wavelength light to ensure that >99% of incident photons were absorbed in the p-type cladding regions. FIG. 3D shows log(M−1) as a function of reverse bias for PIN3, PIN4, and PIN5. The black dashed lines indicate the theoretical gain curves when k=0 (only electron ionization). Interestingly, as the thickness of the multiplier increases, the experimental gain curve approaches that of the theoretical curve, indicating that the thicker the multiplier region, the more closely the device approximates single carrier impact ionization behavior. FIG. 3E shows F as a function of M for PIN3, PIN4, and PIN5. The lowest F was achieved with the thickest multiplier, PIN5. These results confirm the electric-field dependence of the ionization coefficients in AlGaAsSb [16]. The thicker multiplier regions operate at lower electric-fields where the k is smaller, giving lower F. However, the measured F for the thickest structure, PIN5, does not follow McIntyre's curve, increasing more slowly with M at low M. The very low F seen in AlAsSb suggested that the even in thick multiplication regions, non-local and dead space effects can act to reduce F. This behavior may therefore be responsible for the F vs M characteristics seen in PIN5. [17] While the F may well continue to decrease slightly as the multiplication region width increases, the operating voltage would start to become very large in these structures. Therefore, the optimum avalanche multiplier thickness was chosen to be 1020 nm (PIN5), which provides high gain (M˜30) at a voltage of ˜56 V and has a minimal excess noise factor (F˜2.2 at M=30). This F value is much lower than obtainable with an InP or even InAlAs multiplier and is similar to a Si APD [18].

Characterization Results of GAASSB/ALGAASSB SACM APDS: Several iterations of the GaAsSb/AlGaAsSb SACM APDs were grown to optimize the thickness and doping of the grading and charge layers. This study found that a charge layer width of 35 nm with a p-type doping of 6×1017 cm-3 ensures the electric fields in the absorber and the multiplier differ as shown in FIG. 2C.

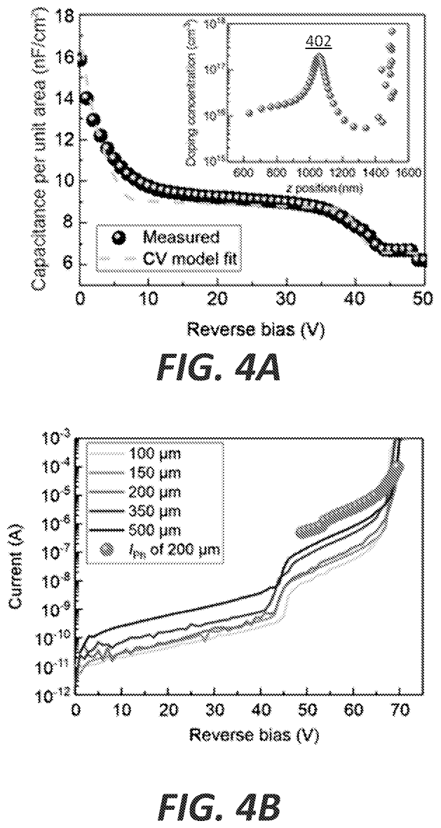

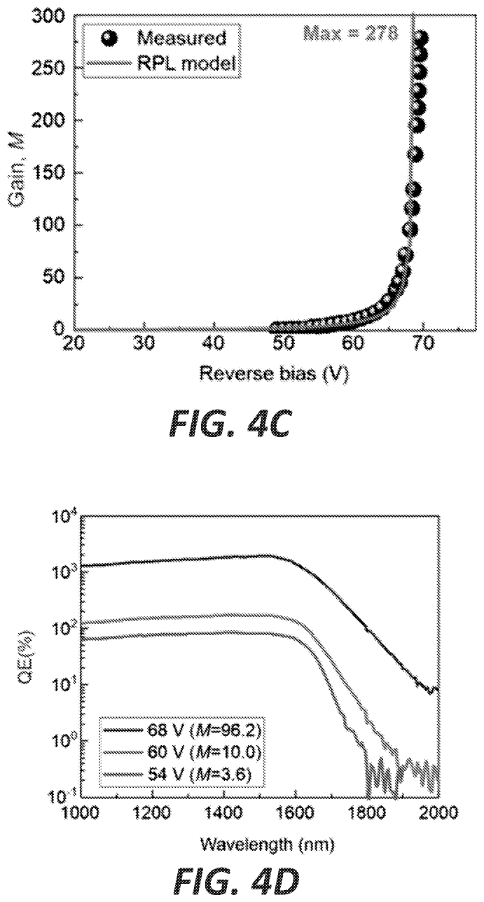

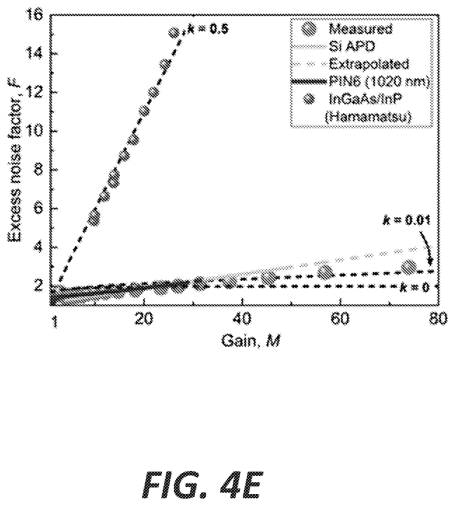

The study recorded results of APD characterizations. FIG. 4A shows the measured CV of the GaAsSb/AlGaAsSb SACM APD. Initially, the C gradually decreases with reverse bias voltage and then drops again at around 42 V, which indicates the punch-through of the electric-field into the absorption layer. To precisely extract the device characteristics modeling was carried out to fit the experimental CV curve. The actual thicknesses and doping concentrations are slightly different to the designed structure described in FIG. 2A. The absorber and multiplier thicknesses were found to be 460 and 1100 nm, respectively. Details of the layer thicknesses and doping of the modeled structure can be found in Supplementary Materials. One observation in the doping profile 402 of the SACM APD is that the peak doping concentration of the charge layer can be slightly lower than designed, which can be caused by dopant diffusion during material growth. However, including the dopant diffusion, the calculated total doping concentration of the charge layer is almost identical to the designed value of 2.1×1012 cm⁻².

The measured dark current for several SACM APDs with differing sizes is shown in FIG. 4B. The dark current scales with the area more than the perimeter of the devices after punch-through, indicating that the total dark current is mainly limited by carriers crossing the charge barrier, resulting in an increase in the dark current. A small deviation of the punch-through voltage between the simulation and experiment may originate from the variation of the doping concentration or thickness in the charge layer across the wafer. Beyond punch-through, the photocurrent (Iph) continues to increase, driven by the avalanche process until it reaches breakdown around 70 V. There is a slight increase in the photocurrent at 53 V, which is probably due to the grading layers' steps that impede electron transport. This phenomenon can be mitigated by linear grading. Accurate determination of the multiplication as a function of bias requires knowledge of the gain at a particular bias. Since the photocurrent is unreliable below 54 V, all analyses on the M and F used data from 54 V onwards. At 54 V the device is fully depleted and the electric field in the multiplication region is high enough to give rise to some gain. The M of the SACM APDs was calculated using the electric-field distribution obtained from CV modeling (FIG. 3A), and the impact ionization coefficients of AlGaAsSb [16], using a random path length (RPL) model [19]. This gave an M of 3.6 at 54 V which was used to convert the photocurrent shown in FIG. 4B into a bias-dependent M. The modeled multiplication at voltages ≥54 V agrees well with the measured photocurrent results as shown in FIG. 4C.

FIG. 4A illustrates measured CV result of the SACM APD and a doping profile 402. FIG. 4B illustrates bias-dependent dark current for different diode sizes and photocurrent (Iph) for 200 pam diameter device at room temperature. Punch-through occurs around 42-45 V, with the photocurrent suddenly increasing by two orders of magnitude higher than the dark current. FIG. 4C illustrates M obtained with a 1550 nm illumination showing a maximum gain of 278. The random path length (RPL) model fits the measured M curve well. FIG. 4D illustrates measured QE spectra of the SACM APD at various reverse bias voltages. FIG. 4E illustrates noise factor, F, as a function of the multiplication gain, M. Notice that the commercial infrared multiplier, InP, has very large F. The AlGaAsSb layer has an F that even better than Si.

The maximum measured M was 278, an order of magnitude improvement over commercial 1550 nm APDs. FIG. 4D shows the measured QE spectra of the SACM APD as a function of wavelength at various reverse biases and hence gains. Comparing the value of the photocurrent at 54 V using 1550 nm in the SACM APD to those in PIN1 and PIN2 at unity gain further corroborated the M value of 3.6.

The QE deduced in the SACM APD at unity gain is relatively low at 21.35% (which can be caused by the thin 460 nm GaAsSb layer used) but nevertheless can still achieve quantum efficiency of 5935.3% (responsivity of 7418 A/W) at maximum gain. One example feature in the QE spectra is that the cut-off tail becomes slightly extended to longer wavelengths (˜1900 nm) as the applied reverse bias voltage increases, due to the Franz-Keldysh effect [20,21]. This can be useful for example applications such as detection of methane (1650 nm), hydrogen chloride (1742 nm), nitrogen oxide (1814 nm) and water vapor (1854 nm, 1877 nm) [22].

The measured F of the SACM APD structure, shown in FIG. 4E, does not follow McIntyre's curve, increasing more slowly with M at low M and appears to have the same F vs M characteristic as seen in PIN5 (FIG. 2(e)). The F is approximately 5× lower than that of commercial InP APDs and even lower than that of a low noise commercial Si APD for M>25.

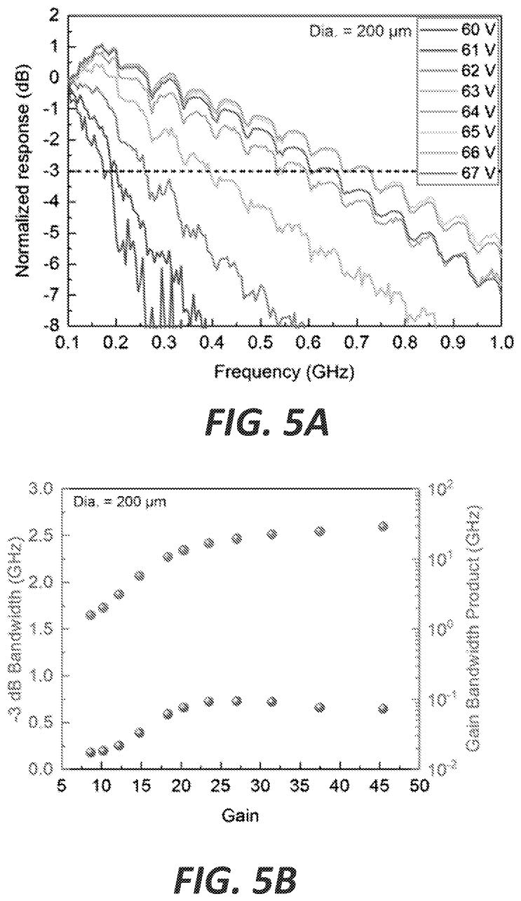

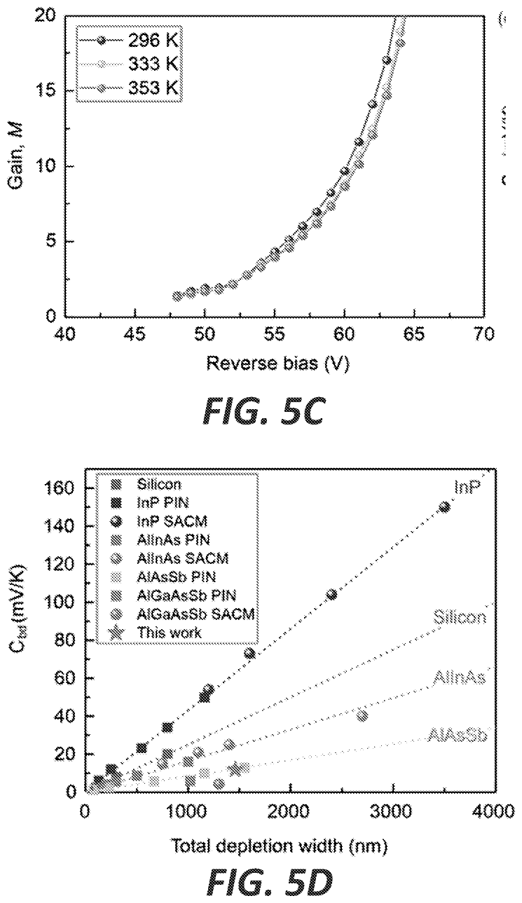

The frequency response and the −3 dB bandwidth of the 200 μm devices are shown in FIGS. 5A and 5B respectively. Measurements were undertaken using a CW 1.55-μm semiconductor laser which was modulated by a Mach-Zehnder modulator (MZM) driven by a vector network analyzer (VNA). Further details are provided throughout the present disclosure. The study focused on 200 μm devices because commercial APD technology for lidar systems can require a large optical window to enhance the input signal. The bandwidth gradually increases from 0.2 GHz (M˜8), saturates at ˜0.7 GHz (M˜25), and then starts dropping (M˜100) due to the avalanche build-Up time. With 65 V reverse bias, the highest −3 dB bandwidth and gain-bandwidth product (GBP) were determined to be 0.7 GHz and 11 GHz, respectively. This bandwidth value is comparable to commercial InP-based APDs (˜0.9 GHz) [5] with a similar diameter and capacitance The bandwidth of these SACM APDs increase with reducing device diameter, which indicates that the bandwidth is limited by the RC time constant of the devices, not by the transit time.

FIG. 5A illustrates frequency of GaAsSb/AlGaAsSb APDs as a function of the operating bias for an example implementation measured using a vector network analyzer (VNA) method [28]. FIG. 5B illustrates the 3 dB bandwidth and Gain Bandwidth Product (GBP) reach 0.7 GHz and 11 GHz at 65 V, respectively. The capacitance of the device limits the bandwidth since the bandwidth decreases with increasing device area. FIG. 5C illustrates measured gain, M, as a function of reverse bias at three different temperatures, 296, 333, and 353 K. FIG. 5D illustrates Cbd versus total depletion width for APDs of various materials, InP [23], Si [24], AlInAs [23], AlAsSb [25,26] and AlGaAsSb [10,30].

One important performance metric in the example APDs studied is the temperature coefficient of breakdown (Cbd), defined as the change in the breakdown voltage with temperature. In general, the breakdown voltage of an APD increases with increasing the temperature due to the increased phonon scattering reducing the ionization coefficients. This can significantly alter the multiplication (or gain) and hence sensitivity as the temperature changes in APDs made of materials such as InP [23] and Si [24]. To determine the Cbd of our device, M at various temperatures, 296 (23° C.), 333 (60° C.) and 353 K (80° C.) were measured as shown in FIG. 5C. The change in voltage with temperature at M=20 was used rather than at breakdown as this should give similar results without the risk of (potentially catastrophic) damage to the devices. The device junction temperatures were accurately measured using the method described in ref [25] and the measured Cbd was ˜11.8 mV/K, which is ˜10× lower than the Hamamatsu device (Cbd=100 mV/K) [5]. FIG. 5D compares Cbd for this SACM APD and several other APD technologies as a function of total depletion thickness. The AlGaAsSb SACM APDs present significantly lower Cbd than InP, AlInAs and Si based APDs and are comparable to results reported for AlAsSb [25], AlGaAsSb [10] and AlInAsSb [26] based APDs. Ong et al. [27] showed that the alloy disorder potential was responsible for the large differences seen in the Cbd of different semiconductors and Monte Carlo modelling by Jin et al. [25] showed that the increased alloy scattering relative to the phonon scattering in the Sb based alloys reduces the temperature dependence of the ionization coefficients, resulting in a much smaller Cbd. This suggests that these SACM APDs will not require significant temperature stabilization, which can eliminate the need for a cooling subsystem.

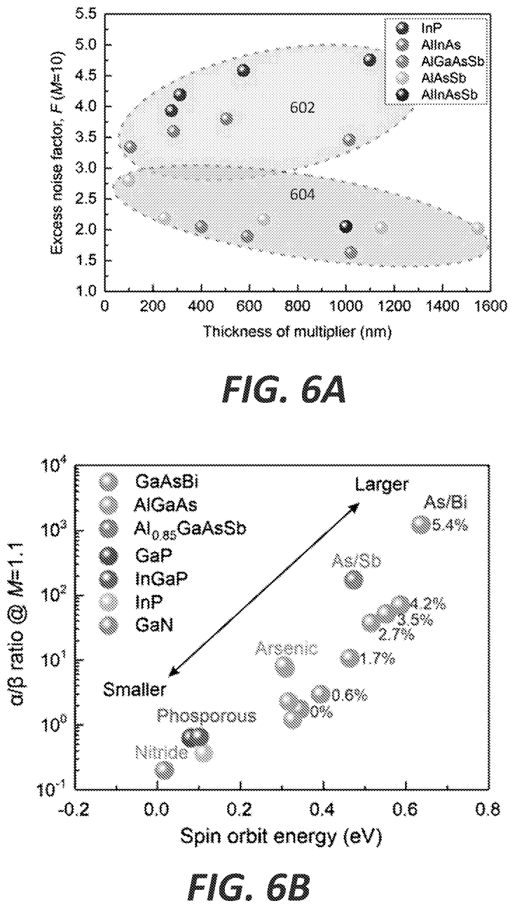

Extremely low excess noise (and large a/ratio) can be demonstrated with various As/Sb mixed alloys on InP substrates, such as AlGaAsSb [6,7], AlAsSb [31], and AlInAsSb [32]. As shown in FIG. 6A illustrates their noise values (ellipse 604) are significantly smaller than those of P- and As-bearing materials (ellipse 602). This observation, combined with the observed sub-McIntyre behavior, shows that the ionization behavior of large group V atom APDs (Sb) can be different compared to those of smaller group V species (P and As). Adding large Bi atoms into GaAs mainly engineers the valence band structure [33] and so, increases the spin-orbit splitting energy (Δso). Oguzman et al. [34] showed that in GaAs, the hole ionization process was largely initiated from the split-off band. Increasing Δso makes the transfer of holes from the heavy and light hole bands into the split-off band more difficult and hence reduces the hole impact ionization as shown in the GaAsBi system [35]. To investigate the effect of Δso on the α/β ratio for various material systems, we plot the calculated α/β ratio (at the electric-fields corresponding to M=1.1 in 1 μm p+-i-n+ diodes) as a function of Δso, as shown in FIG. 6B. It is clear that the (x/B ratio increases with increasing Δso and this correlates with the increasing size of the group V species in the alloys (N→P→As→As/Sb→As/Bi). With only 5.4% incorporation of Bi, Δso can reach up to ˜0.6 eV and result in a α/β ratio that is even larger than Al0.85GaAsSb. The ionization coefficients of InP, InAlAs and AlAsSb show that the electric-field dependence of α is identical in all three materials but it is the that decreases as Δso increases [36]. Similar behavior is seen in the GaAsBi material system with a changing only very slightly with increasing Bi but β decreasing dramatically [33]. These findings show that the valence band structure in bulk semiconductors can be engineered to obtain deterministic gain.

FIG. 6A illustrates F at M=10 as a function of multiplier thickness for various material systems on InP substrates: AlGaAsSb (an example implementation of the present disclosure), InP [4], InAlAs [37], AlAsSb [31,38], and AlInAsSb [32]. The first ellipse 602 contains materials without Sb while the second ellipse 604 contains Sb bearing materials. FIG. 6B illustrates α/β ratio at M=1.1 versus spin orbit energy for various material systems: GaN [39,40], GaP [41,42], InGaP [43,44], InP [25,45], AlxGa1−xAs [46-48], and GaAs1−xBix [35]. The spin orbit energy of Al0.85GaAsSb was theoretically calculated using a 14-band keep method in an example implementation described herein.

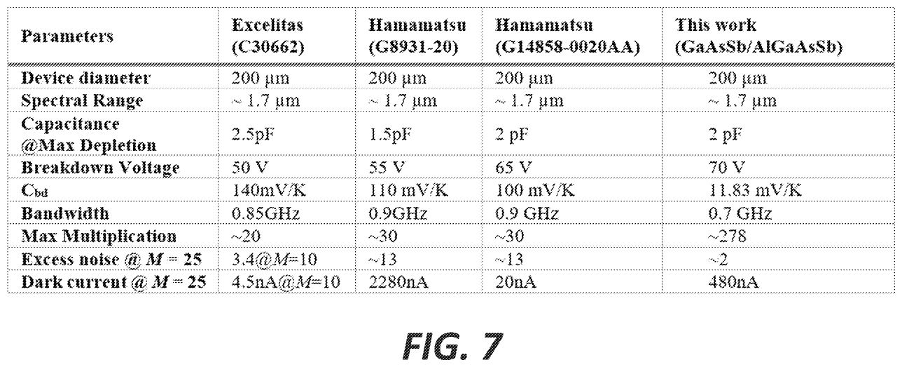

FIG. 7 compares an example implementation of the present disclosure with a non-optimized GaAsSb/AlGaAsSb SACM APD to three commercially available, 200 μm diameter InGaAs APDs to benchmark the performance of the example device. The Hamamatsu G14858-0020AA is a low dark current design [5]. The 200 μm GaAsSb/AlGaAsSb SACM APD (an example implementation described herein) is capable of an M that is ˜10× higher, an F (at M=25) that is 6.5× lower, Cbd that is ˜10× lower, and a similar bandwidth. However, the QE of the SACM APD (21.35%) at the unity gain point is less than that of this Hamamatsu APD (˜65%), which can be attributed to the thin GaAsSb absorber (460 nm) used here and lack of any AR coating. Therefore, the a performance limiting factor for the example device can be the bulk dark current from the GaAsSb absorption region which is 24× higher but even this compares favorably with the Hamamatsu G8931-20 variant. Comparison with the Excelitas APD is complicated by the fact that its dark current and F is only provided at M=10 but on most metrics, the GaAsSb/AlGaAsSb compares favorably. Further optimization of the GaAsSb growth to reduce the dark currents to levels seen in InGaAs together with the use of an AR coating and a 2 μm thick GaAsSb absorber will improve the performance of this SACM APD significantly. This would increase the QE at unity gain to 87% giving potentially a maximum multiplied QE of 24,186%. The capacitance is also expected to be almost half, and this should lead to a doubling of the RC-limited device bandwidth to 1.4 GHz. The Cbd will also double if the total depletion width doubles but at <24 mV/K, it is still >4× better than these commercial InGaAs APDs.

The study demonstrated that a room temperature, high gain, and extremely low excess noise GaAsSb/AlGaAsSb SACM APD on InP shows improved sensitivity over Si and other APDs for 1550 nm detection. The SACM APD growth and design can be improved to reduce the bulk dark currents, increase the multiplied quantum efficiency with low excess noise and extend the bandwidth from this initial demonstration. These characteristics will provide significant performance enhancements in lidar systems and other applications that require high sensitivity and fast response time APDs.

The present disclosure includes methods of material growth. In one example implementation, five p+-i-n+ samples and one SACM sample were grown on semi-insulating InP substrates using a random alloy growth technique in a solid-state molecular beam epitaxy (MBE) reactor. The materials were grown as random alloys (RAs). For group V cells, we used RIBER VAC 500 and Veeco Mark V valved crackers for As and Sb, respectively. To achieve very low background doping concentration for both p+-i-n+ GaAsSb and AlGaAsSb, calibration runs were performed at various growth conditions such as growth rate, V/Ill beam equivalent pressure (BEP) ratio, and growth temperature. [6,7].

The present disclosure also includes methods of device fabrication. Optimizing the device fabrication process is important to achieve high gain and low noise SACM APDs. If the fabrication is not done well, high leakage current and early edge breakdown prevent characterization of representative gain and noise of the APDs. To perform the characterizations, iterative fabrication runs were carried out with characterization of current and noise characteristics to guide the optimization. The fabrication for the SACM APDs was done with a conventional lithography and wet etching processes to delineate a clear mesa shape of the devices, and the surface was covered by SU-8 for passivation. Lastly, Ti/Au were deposited on the top and bottom contact layers to make ohmic contacts. The low series resistance for all devices was confirmed by forward IV characteristics [6,7].

IV and CV measurements for an example implementation were also performed in the study. The dark current-voltage measurements were performed with a HP4140B picoammeter and a probe station. Capacitance-voltage measurements were undertaken using a HP4275A LCR meter as a frequency of 100 KHz. The depletion width and background doping concentration were determined with a static dielectric constant of 11.4 for AlGaAsSb and 14.1 for GaAsSb.

Multiplication and excess noise for an example implementation was also measured in the study. A transimpedance amplifier-based circuit with a center frequency of 10 MHz and a bandwidth of 4.2 MHz was used to determine the multiplication and excess noise in these structures as described in ref [49]. Phase-sensitive detection was used to remove the effects of the DC dark leakage current. The measurement setup is calibrated by using a reference device (SFH2701 Silicon PIN photodiode) which operates with shot noise only. The measured noise power of the DUT is compared to the measured noise power of the reference device at a given photocurrent to determine excess noise factor. A Thorlabs fiber-coupled LED (M.450F1) with an emission peak at 1550 nm was used to illuminate the devices for multiplication and excess noise measurements. The gain value of the GaAsSb/AlGaAsSb SACM at a given voltage is determined by comparing the absolute photocurrent value to a GaAsSb p+-i-n+ diode of identical optical sensing area at unity gain, correcting for differences in photon absorption.

Quantum efficiency for an example implementation was measured in the study. Quantum efficiency measurements were performed to study the optical properties of the SACM. A 100 W tungsten bulb source was focused into a monochromator (IHR320). The output light from the monochromator was focused onto the DUT using optical lenses. The light was modulated at 180 Hz by a mechanical chopper to remove any DC dark leakage current, and photocurrent is measured using a lock-in amplifier. The DUT is biased with Keithley 236 source meter unit. A InGaAs photodiode (FD05D) sold under the trademark Thorlabs, with known responsivity, was used as a reference sample to calculate the relative power of the monochromator at each wavelength.

Bandwidth measurements were also recorded in the study. A CW optical signal from a 1.55 μm semiconductor laser was passed through a polarization controller and then modulated by a LiNbO3 Mach-Zehnder modulator (MZM). A bias was applied to the modulator at the quadrature point, and it was driven by a vector network analyzer (VNA). Then, the modulated optical signal was focused onto the SACM device via a lensed fiber, and a G-S probe collects the photo-response. The VNA using a bias-tee measures the RF photo-response. [28].

### REFERENCES

[1] U. N. Singh, T. F. Refaat, S. Ismail, K. J. Davis, S. R. Kawa, R. T. Menzies, and M. Petros, “Feasibility study of a space-based high pulse energy 2 μm CO2 IPDA lidars,” Appl. Opt. 56, 6531 (2017).
[2] P. F. McManamon, “Lidar Technologies and Systems” (SPIE, 2019).
[3] R. McIntyre, “Multiplication noise in uniform avalanche diodes”, IEEE Trans. Electron Devices. 164 (1966).
[4] P. Yuan, C. C. Hansing, K. A. Anselm, C. V. Lenox, H. Nie, A. L. Holmes, Jr., B. G. Streetman, and J. C. Campbell, “Impact ionization characteristics of Ill-V semiconductors for a wide range of multiplication region thicknesses”, IEEE J. Quantum Electron. 36, 198 (2000).
[5] Hamarnatsu Product Datasheet: InGaAs APD (G14858-0020AA), <https://www.hamamatsu.com/content/dam/hamamatsu-photonics/sites/documents/99_SALES_LIBRARY/ssd/g14858-0020aa_kapd1068e.pdf> (2019).
[6] S. Lee, S. H. Kodati, B. Guo, A. H. Jones, M. Schwartz, M. Winslow, C. H. Grein, T. J. Ronningen, J. C. Campbell, and S. Krishna, “Low noise Al0.85Ga0.15As0.56Sb0.44 avalanche photodiodes on InP substrates”, Appl. Phys. Lett. 118, 081106 (2021).
[7] S. Lee, B. Guo, S. H. Kodati, H. Jung, M. Schwartz, A. H. Jones, M. Winslow, C. H. Grein, T. J. Ronningen, J. C. Campbell, and S. Krishna, “Random alloy thick AlGaAsSb avalanche photodiodes on InP substrates”, Appl. Phys. Lett. 120, 071101 (2022).
[8] M. S. Park, and J. H. Jang, “GaAs0.5Sb0.5 lattice matched to InP for 1.55 μm photo-detection”, Electron. Lett. 44, 549 (2008).
[9] H. Inada, K. Miura, H. Mori, Y. Nagai, Y. Iguchi, and Y. Kawamura, in Infrared Technology and Applications XXXVI. 76603N (SPIE, 2010).
[10] Y. Cao, T. Osman, E. Clarke, P. K. Patil, J. S. Ng, and C. H. Tan, “A GaAsSb/AlGaAsSb Avalanche Photodiode with a very small Temperature Coefficient of Breakdown Voltage”, J. Light. Technol. 40, 4709 (2022).
[11] Y. Xiao, Z. Li, and Z. S. Li, in Photonic Fiber and Crystal Devices: Advances in Materials and Innovations in Device Applications XIV. 114980R (SPIE, 2020).
[12] S. Xie, X. Zhou, S. Zhang, D. J. Thomson, X. Chen, G. T. Reed, J. S. Ng, and C. H. Tan, “InGaAs/AlGaAsSb avalanche photodiode with high gain-bandwidth product”, Opt. Express. 24, 24242 (2016).
[13] D. Hahn, O. Jaschinski, H.-H. Wehmann, A. Schlachetzki, and M. V. Ortenberg, “Electron-concentration dependence of absorption and refraction in n-In0.53Ga0.47As near the band-edge”, J. Electron. Mater. 24, 1357 (1995).
[14] I. Vurgaftman, and J. R. Meyer, “Band parameters for Ill-V compound semiconductors and their alloys”, J. Appl. Phys. 89, 5815 (2001).
[15] P. Delvin, H. M. Heravi, and J. C. Woolley, “Electron effective mass values in GaAsxSb1−x alloys”, Can. J. Phys. 59, 939 (1981).
[16] B. Guo, X. Jin, S. Lee, S. Z. Ahmed, A. H. Jones, X. Xue, B. Liang, H. L. J. Lewis, S. H. Kodati, D. Chen, T. J. Ronningen, C. H. Grein, A. W. Ghosh, S. Krishna, J. P. R. David, and J. C. Campbell, “Impact ionization coefficients of digital alloy and random alloy Al0.85Ga0.15As0.56Sb0.44 in a wide electric field range”, J. Light. Technol. 40, 4758 (2022).
[17] D. S. Ong, A. H. Tan, K. Y. Choo, K. H. Yeoh, and J. P. R. David, “Weibull-Frdchet random path length model for avalanche gain and noise in photodiodes”, J. Phys. D: Appl. Phys. 55, 065105 (2021).
[18] Hamamatsu Product Datasheet: Si APD (S10341 series). <https://www.hamamatsu.com/resources/pdf/ssd/s10341_series_kapdl030e.pdf> (2017).
[19] D. S. Ong, K. F. Li, G. J. Rees, J. P. R. David, and P. N. Robson, “A simple model to determine multiplication and noise in avalanche photodiodes”, J. Appl. Phys. 83, 3426 (1998).
[20] M. J. Sun, K. H. Nichols, W. S. C. Chang, R. O. Gregory, F. J. Rosenbaum, and C. M. Wolfe, “Gallium arsenide electroabsorption avalanche photodiode waveguide detectors”, Appl. Opt. 17, 1568 (1978).
[21] T. E. V. Eck, L. M. Walpita, W. S. C. Chang, and H. H. Wieder, “Franz-Keldysh electrorefraction and electroabsorption in bulk InP and GaAs”, Appl. Phys. Lett. 48, 451 (1986).
[22] W. Weng, J. Larsson, J. Bood, M. Alden, and Z. Li, “Quantitative Hydrogen Chloride Detection in Combustion Environments Using Tunable Diode Laser Absorption Spectroscopy with Comprehensive Investigation of Hot Water Interference”, Appl. Spectrosc. 76, 207 (2022).
[23] L. J. J. Tan, D. S. G. Ong, J. S. Ng, C. H. Tan, S. K. Jones, Y. Qian, and J. P. R. David, “Temperature dependence of avalanche breakdown in InP and InAlAs”, IEEE J. Quantum Electron. 46, 1153 (2010).
[24] D. J. Massey, J. P. R. David, and G. J. Rees, “Temperature dependence of impact ionization in submicrometer silicon devices”, IEEE Trans. Electron Devices. 53, 2328 (2006).
[25] X. Jin, S. Xie, B. Liang, X. Yi, H. Lewis, L. W. Lim, Y. Liu, B. K. Ng, D. L. Huffaker, C. H. Tan, D. S. Ong, and J. P. R. David, “Temperature dependence of the impact ionization coefficients in AlAsSb lattice matched to InP”, IEEE J. Sel. Top. Quantum Electron. 28, 1 (2021).
[26] A. H. Jones, S. D. March, S. R. Bank, and J. C. Campbell, “Low-noise high-temperature AlInAsSb/GaSb avalanche photodiodes for 2-μm applications”, Nat. Photon. 14, 559 (2020).
[27] J. S. L. Ong, J. S. Ng, A. B. Krysa, and J. P. R. David, “Temperature dependence of avalanche multiplication and breakdown voltage in Al0.52In0.48P”, J. Appl. Phys. 115, 064507 (2014).
[28] D. Chen, K. Sun, Y. Shen, A. H. Jones, A. A. Dadey, B. Guo, J. A. McArthur, S. R. Bank, and J. C. Campbell, “Frequency behavior of AlInAsSb nBn photodetectors and the development of an equivalent circuit model”, Opt. Express. 30, 25262 (2022).
[29] S. Xie, and C. H. Tan, “AlAsSb avalanche photodiodes with a sub-mV/K temperature coefficient of breakdown voltage”, IEEE J. Quantum Electron. 47, 1391 (2011).
[30] B. Guo, S. Z. Ahmed, X. Xue, A.-K. Rockwell, J. Ha, S. Lee, B. Liang, A. H. Jones, J. A. McArthur, S. H. Kodati, T. J. Ronningen, S. Krishna, J. S. Kim, S. R. Bank, A. W. Ghosh, and J. C. Campbell, “Temperature dependence of avalanche breakdown of AlGaAsSb and AlInAsSb avalanche photodiodes”, J. Light. Technol. 40, 5934 (2022).
[31] X. Yi, S. Xie, B. Liang, L. W. Lim, J. S. Cheong, M. C. Debnath, D. L. Huffaker, C. H. Tan, and J. P. R. David, “Extremely low excess noise and high sensitivity AlAs0.56Sb0.44 avalanche photodiodes”, Nat. Photon. 13, 683 (2019).
[32] S. H. Kodati, S. Lee, B. Guo, A. H. Jones, M. Schwartz, M. Winslow, N. A. Pfiester, C. H. Grein, T. J. Ronningen, J. C. Campbell, and S. Krishna, “AlInAsSb avalanche photodiodes on InP substrates”, Appl. Phys. Lett. 118, 091101 (2021).
[33] K. Alberi, O. D. Dubon, W. Walukiewicz, K. M. Yu, K. Bertulis, and A. Krotkus, “Valence band anticrossing in GaBixAs1−x”, Appl. Phys. Lett. 91, 051909 (2007).
[34] I. H. Oguzman, Y. Wang, J. Kolnik, and K. F. Brennan, “Theoretical study of hole initiated impact ionization in bulk silicon and GaAs using a wave-vector-dependent numerical transition rate formulation within an ensemble Monte Carlo calculation”, J. Appl. Phys. 77, 225 (1995).
[35] Y. Liu, X. Yi, N. J. Bailey, Z. Zhou, T. B. O. Rockett, L. W. Lim, C. H. Tan, R. D. Richards, and J. P. R. David, “Valence band engineering of GaAsBi for low noise avalanche photodiodes”, Nat. Commun. 12, 1 (2021).
[36] X. Yi, S. Xie, B. Liang, L. W. Lim, X. Zhou, M. C. Debnath, D. L. Huffaker, C. H. Tan, and J, P. R. David, “Demonstration of large ionization coefficient ratio in AlAs0.56Sb0.44 lattice matched to InP” Sci. Rep. 8, 1 (2018).
[37] Y. L. Goh, A. R. J. Marshall, D. J. Massey, J. S. Ng, C. H. Tan, M. Hopkinson, J. P. R. David, S. K. Jones, C. C. button, and S. M. Pinches, “Excess Avalanche Noise in In0.52Al0.48As”, IEEE J. Quantum Electron. 43, 503 (2007).
[38] J. Xie, S. Xie, R. C. Tozer, and C. H. Tan, “Excess noise characteristics of thin AlAsSb APDs”, IEEE Trans. Electron Devices. 59, 1475 (2012).
[39] L. Cao, J. Wang, G. Harden, H. Ye, R. Stillwell, A. J. Hoffman, and P. Fay, “Experimental characterization of impact ionization coefficients for electrons and holes in GaN grown on bulk GaN substrates”, Appl. Phys. Lett. 112, 262103 (2018).
[40] A. Wolos, Z. Wilamowski, C. Skierbiszewski, A. Drabinska, B. Lucznik, I. Grzegory, and S. Porowski, “Electron spin resonance and Rashba field in GaN-based materials”, Physica B Condens. 406, 2548 (2011).
[41] R. A. Logan, and A. G. Chynoweth, “Charge Multiplication in GaP p-n Junctions”, J. Appl. Phys. 33, 1649 (1962).
[42] S. E. Stokowski, and D. D. Sell, “Reflectivity and (dR/dE)/R of GaP between 2.5 and 6.0 eV”, Phys. Rev. B. 5, 1636 (1972).
[43] C. H. Tan, R. Ghin, J. P. R. David, G. J. Rees, and M. Hopkinson, “The effect of dead space on gain and excess noise in In0.48Ga0.52P p+in+ diodes”, Semicond. Sci. Technol. 18, 803 (2003).
[44] R. G. Alonso, A. Mascarenhas, S. Froyen, G. S. Horner, K. Bertness, and J. M. Olson, “Polarized piezomodulated reflectance study of spontaneous ordering in GaInP2”, Solid State Commun. 85, 1021 (1993).
[45] J. Peretti, H.-J. Drouhin, D. Paget, and A. Mircea, “Band structure of indium phosphide from near-band-gap photoemission”, Phys. Rev. B. 44, 7999 (1991).
[46] M. Levinshtein, Handbook Series on Semiconductor Parameters. Vol. 1 (World Scientific, 1997).
[47] S. A. Plimmer, J. P. R. David, G. J. Rees, P. N. Robson, “Ionization coefficients in AlxGa1−xAs (x=0-0.60)”, Semicond. Sci. Technol. 15, 692 (2000).
[48] B. K. Ng, J. P. R. David, S. A. Plimmer, G. J. Rees, R. C. Tozer, M. Hopkinson, and G. Hill, “Avalanche multiplication characteristics of, Al0.8Ga0.2As diodes”, IEEE Trans. Electron Devices. 48, 2198 (2001).
[49] K. S. Lau, C. H. Tan, B. K. Ng, K. F. Li, R. C. Tozer, J. P. R. David, and G. J. Rees, “Excess noise measurement in avalanche photodiodes using a transimpedance amplifier front-end”, Meas. Sci. Technol. 17, 1941 (2006).

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An avalanche photodiode (APD) comprising:
a substrate; and
a separate absorption charge and multiplication (SACM) heterostructure disposed on the substrate, wherein the SACM heterostructure comprises:
an absorber comprising gallium arsenide antimonide (GaAsSb); and
a multiplier comprising aluminum gallium arsenide antimonide (AlGaAsSb), wherein the APD exhibits a gain (M) of greater than 50.

2. The APD of claim 1, wherein the APD exhibits M of greater than 50 at about 1550 nm.

3. The APD of claim 1, wherein the APD exhibits M of greater than 100 at about 1550 nm.

4. The APD of claim 1, wherein APD exhibits an excess noise factor of less than 3 at M of about 70.

5. The APD of claim 1, wherein APD exhibits an excess noise factor of 2.2 or less at M of about 50.

6. The APD of claim 1, wherein the SACM heterostructure further comprises a charge layer arranged between the absorber and the multiplier.

7. The APD of claim 6, wherein the charge layer comprises doped AlGaAsSb.

8. The APD of claim 7, wherein the charge layer has a total doping concentration is about 2.1×10¹² cm⁻².

9. The APD of claim 6, wherein the charge layer has a p-type doping of between 1×10¹⁶ cm⁻³ and 1×10¹⁸ cm⁻³.

10. The APD of claim 6, wherein the charge layer is between 10 nm and 200 nm thick.

11. The APD of claim 1, wherein the SACM heterostructure further comprises a grading layer arranged between the absorber and the multiplier.

12. The APD of claim 11, wherein the grading layer comprises linearly-graded or step-graded AlGaAsSb.

13. The APD of claim 11, wherein the grading layer comprises unintentionally doped (UID) AlGaAsSb.

14. The APD of claim 11, wherein the grading layer is approximately 90 nm thick.

15. The APD of claim 11, wherein the grading layer is between 50 nm and 2000 nm thick.

16. The APD of claim 11, wherein a composition of Al in the grading layer is graded from 0% to 85%.

17. The APD of claim 1, wherein the substrate comprises indium phosphide (InP).

18. The APD of claim 1, wherein the multiplier is arranged in a high electric field region.

19. The APD of claim 1, wherein the multiplier is between 300 nm and 3000 nm thick.

20. The APD of claim 1, wherein the multiplier is about 1020 nm thick.

21. The APD of claim 1, wherein the absorber is arranged in a low electric field region.

22. The APD of claim 1, wherein the absorber is between 300 nm and 1000 nm thick.

23. An avalanche photodiode (APD) comprising:
a substrate; and
a separate absorption charge and multiplication (SACM) heterostructure disposed on the substrate, wherein the SACM heterostructure comprises:
an absorber comprising gallium arsenide antimonide (GaAsSb); and
a multiplier comprising aluminum gallium arsenide antimonide (AlGaAsSb), wherein APD exhibits an excess noise factor of less than 3.

24. The APD of claim 23, wherein the APD exhibits a gain (M) of greater than 50.

25. The APD of claim 23, wherein the SACM heterostructure further comprises a charge layer arranged between the absorber and the multiplier.

26. The APD of claim 25, wherein the charge layer comprises doped AlGaAsSb.

27. The APD of claim 23, wherein the SACM heterostructure further comprises a grading layer arranged between the absorber and the multiplier.

28. The APD of claim 27, wherein the grading layer comprises linearly-graded or step-graded AlGaAsSb.

29. The APD of claim 27, wherein the grading layer comprises unintentionally doped (UID) AlGaAsSb.

30. The APD of claim 23, wherein the substrate comprises indium phosphide (InP).
